(19) United States
(12) Patent Application Publication
(10) Pub. No.: US 2009/0133627 A1
(43) Pub. Date: May 28, 2009

(54) SUBSTRATE PROCESSING APPARATUS AND METHOD, AND GAS NOZZLE FOR IMPROVING PURGE EFFICIENCY

(75) Inventors: Hiroshi Shinriki, Matsudo-shi (JP); Mikio Suzuki, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/354,358

(22) Filed: Jan. 15, 2009

Related U.S. Application Data
(62) Division of application No. 11/233,093, filed on Sep. 23, 2005.
Application No. 11/233,093 is a continuation-in-part of application No. PCT/JP03/15677, filed on Dec. 8, 2003.

(30) Foreign Application Priority Data
Mar. 24, 2003 (JP) 2003-079503

(51) Int. Cl. C23C 16/54

(52) U.S. Cl. 118/715

(57) ABSTRACT

A substrate processing apparatus capable of efficiently purging not only a process space but also the inside of a processing gas feed nozzle when a multi element compound film is formed on a substrate by laminating a molecular layer thereon, wherein an exhaust line is connected to one end of the processing gas feed nozzle jetting the processing gas in a laminar flow into the process space along the surface of the treated substrate, and the processing gas or purge gas is fed from the other end thereof.

### CROSS-REFERENCE TO RELATED APPLICATIONS

This application is a divisional of and claims the benefits of U.S. application Ser. No. 11/233,093, filed Sep. 23, 2005, which is a Continuation-In-Part Application of PCT International Application No. PCT/JP03/015677 filed on Dec. 08, 2003, which designated the United States. The entire content of these applications is incorporated herein by reference to the extent that such incorporation does not create an issue of new matter.

### FIELD OF THE INVENTION

The present invention relates to a fabrication of a semiconductor device; and, more particularly, to a vapor phase deposition technology of a dielectric film or a metal film.

### BACKGROUND OF THE INVENTION

Conventionally, a metal film, an insulating film or a semiconductor film of high quality has been generally formed on a surface of a substrate to be processed by an MOCVD method, in a field of a semiconductor device fabrication technology.

Meanwhile, recently, there has been studied an atomic layer deposition (ALD) technology for forming a high dielectric film (so-called a high-K dielectric film) on a surface of a substrate to be processed by accumulating thereon an atomic layer one by one, specifically in case of forming a gate insulating film of an ultra-fine semiconductor device.

In the ALD method, a metal compound molecule containing a metal element, which forms a high-K dielectric film, is supplied as a gaseous source material into a processing space containing a substrate to be processed, so that about one atomic layer of the metal compound molecule is chemically adsorbed on a surface of the substrate to be processed. After the gaseous source material gas is purged from the processing space, an oxidizing agent such as H₂O or the like is supplied thereinto to decompose the metal compound molecule that has been adsorbed on the surface of the substrate to be processed, to thereby form a metal oxide film of about one atomic layer.

Further, after the oxidizing agent is purged from the processing space, the aforementioned processes are repeatedly performed to form a metal oxide film, i.e., a high-K dielectric film, of a desired thickness.

As mentioned above, the ALD method employs a chemical adsorption of a source material (compound molecule) on the surface of the substrate to be processed, and specifically, has a characteristic of a superior step coverage. A high-quality film can be formed at a temperature in the range of 400˜500° C., or below the above range. Thus, the ALD method is considered as an effective technology in the fabrication of a memory cell capacitor of DRAM wherein a dielectric film needs to be formed on a complicated feature, as well as a gate insulating film of an ultra-high speed transistor.

Reference 1: Japanese Patent Laid-open Application No. 2002-151489

FIG. 1 shows a configuration of a substrate processing apparatus 10 described in Japanese Patent Laid-open Application No. 2002-151489.

Referring to FIG. 1, the substrate processing apparatus 10 includes a reaction vessel 11 for accommodating therein a substrate to be processed 12. Herein, the reaction vessel 11 is formed of an outer vessel 101 made of Al or the like, and an inner reaction vessel 102 made of quartz glass. The inner reaction vessel 102 is formed inside the outer vessel 101 to be accommodated in a recess covered by a cover plate 101A forming a part of the outer vessel 101.

The inner reaction vessel 102 is formed of a quartz bottom plate 102A covering a bottom surface of the outer vessel 101 in the recess; and a quartz cover 101B covering the quartz bottom plate 102A therein. Further, at a bottom portion of the outer vessel, there is formed a circular opening 101D for accommodating therein a disc-shaped substrate supporting table 103 for supporting the substrate 12 to be processed. Inside the substrate supporting table 103, there is installed a heating unit (not shown).

The substrate supporting table 103 is supported by a lower vessel 104 such that it can be moved rotatably and vertically. The substrate supporting table 103 is supported in such a manner that it can be moved vertically between an uppermost process position and a lowest substrate loading/unloading position, wherein the process position is determined such that the surface of the substrate 12 to be processed on the supporting table 103 roughly coincides with that of the quartz bottom plate 102A.

Meanwhile, the substrate loading/unloading position is set to correspond to a substrate loading/unloading opening 104A formed at a sidewall of the lower vessel 104. In case when the substrate supporting table 103 is lowered at the substrate loading/unloading position, a transfer arm 104B is inserted from the substrate loading/unloading port 104A to unload the substrate 12 lifted up from the surface of the substrate supporting table 103 by lifter pins (not shown), and thus the substrate is transferred for a next processing. Further, a new substrate 12 to be processed is loaded into the lower vessel 104 through the substrate loading/unloading opening 104A by the transfer arm 104B to be mounted on the substrate supporting table 103.

The substrate supporting table 103 supporting the new substrate 12 to be processed is supported such that it can be moved rotatably and vertically by a rotation axis 105B supported by a magnetic seal 105A inside a bearing 105. Herein, a space where the rotation axis 105 is vertically moved is airtightly sealed by partitions of a bellows 106 and the like.

At the substrate supporting table 103, there is installed a guide ring 103A made of quartz to surround the substrate 12 to be processed.

The sidewall of the opening 101D formed at the bottom portion of the outer vessel 101 is covered with a quartz liner 101d, which is further extended downward to cover the inner wall of the lower vessel 104.

At both sides of the opening 101D at the bottom portion of the outer vessel 101, there are formed exhaust groove portions 101a and 101b connected to gas exhaust units, respectively. Herein, the exhaust groove portions 101a and 101b are exhausted through conductance valves 15A and 15B via conduction lines 107a and 107b, respectively. In FIG. 1, the conductance valve 15A is set to be closed, and the conductance valve 15B is set to be opened.

The exhaust groove portions 101a and 101b are covered with a liner 108 made of quartz glass; and slit shaped openings 109A and 109B respectively corresponding to the exhaust groove portions 101a and 101b are formed at the quartz bottom plate 102A. In the embodiment shown in FIG. 1, a rectifying plate 109, in which a gas exhaust port 14A or 14B is formed at the slit shaped opening 109A or 109B, is configured to facilitate an exhaustion of the inner reaction vessel 102.

Further, inside the inner reaction vessel 102, quartz gas nozzles 13A and 13B are respectively installed at peripheries of the exhaust groove portions 101b and 101a so as to face each other with the wafer 12 therebetween.

The quartz gas nozzles 13A and 13B are connected to source gas supply lines 16a and 16b and purge gas lines 100a and 100b via switching valves 16A and 16B, respectively. Still further, in the substrate processing apparatus 10 of FIG. 1, the switching valves 16A and 16B are connected to purge lines 100c and 100d, respectively.

A first processing gas introduced through the gas nozzle 13A flows through the inner reaction vessel 102 along the surface of the substrate 12 to be processed, to thereby be exhausted through the conductance valve 15A via the opposite gas exhaust port 14A. In the same manner, a second processing gas introduced through the gas nozzle 13B flows through the inner reaction vessel 102 along the surface of the substrate 12 to be processed, to thereby be exhausted through the conductance valve 15B via the opposite gas exhaust port 14B. As mentioned above, by alternately allowing the first and the second processing gas to flow respectively through the gas exhaust port 14A from the gas nozzle 13A and through the gas exhaust port 14B from the gas nozzle 13B, a film in which an atomic layer becomes a unit thickness can be formed.

Meanwhile, in the substrate processing apparatus 10 of FIG. 1, there may be a case where plural processing gases are alternately supplied into one processing gas supply port, e.g., a processing gas supply port 13A, in case of forming, particularly, a multi-component high dielectric film or the like.

FIG. 2 shows a state in the vicinity of the processing gas supply port 13A in the substrate processing apparatus of FIG. 1, in case where a TMA gas and an organic Hf (HfMO) gas are alternately supplied into the processing gas supply port 13A, as mentioned above. Such a state is the same as in the vicinity of the processing gas supply port 13B, but the explanation thereof will be omitted.

Referring to FIG. 2, in the processing gas supply port 13A, there are provided ports 13a and 13b into which the HfMO and the TMA gas are supplied at different positions in the longitudinal direction thereof; and the HfMO gas in a line L1 is supplied into the port 13a via a valve V1. In the same manner, the TMA gas in a line L2 is supplied into the port 13b via a valve V2.

The line L1 is connected to a vent line Lv via a valve V7, and the line L2 is connected to the vent line Lv via a valve V8. If the valve V1 is closed and the valve V3 is opened, Ar gas in a purge line Lp1 is supplied into the processing gas supply port 13A via the port 13a. Further, if the valve V2 is closed and the valve V4 is opened, Ar gas in a purge line Lp2 is supplied into the processing gas supply port 13A via the port 13b. Still further, in a state where the valve V3 is closed, Ar gas in the purge line Lp1 is exhausted through the vent line Lv via an additional valve VS; and, in a state where the valve V4 is closed, Ar gas in the purge line Lp2 is exhausted through the vent line Lv via an additional valve V6.

By installing such a gas supply unit in the processing gas supply port 13A, it is possible to supply the TMA and the HfMO gas into the reaction vessel 102, alternately. For example, a high dielectric film such as ZrAl₂O₅ can be formed through an atomic layer deposition.

However, in case of using the processing gas supply port 13A or 13B having a configuration of FIG. 2, the source gas is likely to remain in the processing gas supply port 13A; and, even though a purge is performed by using a purge gas such as Ar or the like when switching the processing gas, the processing gas used for the prior processing remains in the processing gas supply port 13A when a following processing gas is supplied thereinto. Such a problem is serious in the substrate processing apparatus 10 wherein the processing gas supply port 13A has a long and slender injection opening of a small area to form in the reaction vessel 102 a laminar flow of the processing gas supplied from the processing gas supply port 13A.

Further, in the purge processing using an Ar gas in the line Lp1 or Lp2, since the processing gas remaining in the processing gas supply port 13A is discharged into the reaction vessel 102, the adsorption of the processing gas molecule, which is unnecessary for the purge processing, may be undesirably generated.

Still further, in the configuration of FIG. 2, if one processing gas has a property that reacts with the other one, there may be a concern that a processing gas to be supplied reacts with the remaining processing gas used for the prior processing to thereby generate particles. Therefore, for securely avoiding the problem of particle generation as mentioned above, it is necessary to install an additional processing gas supply port independently around the processing gas supply port 13A. However, in such a configuration, it is difficult to reduce a volume of the processing space, i.e., the reaction vessel 102. In a technology of forming a film by repeatedly supplying the processing gas and the purge gas, e.g., atomic layer deposition technology or the like, an inner volume of the reaction vessel needs to be as small as possible such that rapid purge can be realized. However, in the configuration of FIG. 2, it is difficult to reduce the inner volume of the reaction vessel, and it takes much time to perform the purge.

### SUMMARY OF THE INVENTION

It is, therefore, an object of the present invention to provide a new and useful substrate processing apparatus.

Specifically, it is another object of the present invention to provide a substrate processing apparatus having a processing gas introduction port capable of efficiently performing a purge.

It is still another object of the present invention to provide a substrate processing apparatus capable of switching a processing gas efficiently.

In accordance with one aspect of the present invention, there is provided a substrate processing apparatus including: a reaction vessel having a substrate supporting table for supporting a substrate to be processed; and a processing gas supply unit for supplying into the reaction vessel a processing gas in the form of a laminar flow along a surface of the substrate to be processed, wherein the processing gas supply unit includes a processing gas nozzle for forming the laminar flow of the processing gas, the processing gas nozzle being provided in the reaction vessel and extended in a direction substantially normal to that of the laminar flow; and wherein one end of the processing gas supply nozzle is connected to a processing gas supply line for supplying the processing gas, and an opposite end thereof is connected to an exhaust line.

In accordance with another aspect of the present invention, there is provided a substrate processing apparatus, including: a reaction vessel having a substrate supporting table for supporting a substrate to be processed, the reaction vessel having a first exhaust port formed at a first side of the substrate supporting table and a second exhaust port formed at a second side facing the first side of the substrate supporting table; a first processing gas supply unit, provided at the second side of the reaction vessel, for supplying a first laminar flow of a first processing gas into the reaction vessel; and a second processing gas supply unit, provided at the first side of the reaction vessel, for supplying a second laminar flow of a second processing gas into the reaction vessel, wherein the first and the second exhaust port have a first and a second slit shape, respectively, extended in a direction substantially normal to those of the first and the second laminar flow; the first exhaust port is connected to a first valve having a valve body in which a first opening corresponding to the first slit shape is provided; the second exhaust port is connected to a second valve having a valve body in which a second opening corresponding to the second slit shape is provided; and the first and the second opening are provided to be shifted in a direction substantially normal to extending directions of the first and the second slit shape, respectively.

In accordance with still another aspect of the present invention, there is provided a substrate processing method, including the steps of: supplying a laminar flow of a first processing gas from a first processing gas nozzle provided at a first side of a substrate to be processed towards a second side facing the first side of the substrate to be processed, along a surface of the substrate to be processed, thereby, allowing molecules of the first processing gas to be adsorbed on the surface of the substrate; removing the first processing gas from a processing space including the substrate to be processed and the first processing gas nozzle; supplying a laminar flow of a second processing gas towards the first side from a second processing gas nozzle provided at the second side, along the surface of the substrate to be processed, thereby, allowing the second processing gas to react with the molecules of the first processing gas adsorbed on the surface of the substrate; and removing the second processing gas from the processing space and the second processing gas nozzle.

In accordance with still another aspect of the present invention, there is provided a gas nozzle including: a hollow member extending from a first end to a second end; a conduction line accommodated in the hollow member and extended from a third end to a fourth end, the third and the fourth end corresponding to the first and the second end, respectively; plural openings formed in the conduction line along a length direction thereof; a slit shaped gas injection opening formed in the hollow member along the extending direction thereof; a gas introduction port provided at the third end of the conduction line; a gas exhaust port provided at the fourth end of the conduction line; and a gas introduction port provided at the hollow member to communicate with an inside thereof.

In accordance with the present invention, the processing gas is introduced from one end of the processing gas supply nozzle and discharged through the other end thereof. Thus, by injecting the purge gas into one end after injecting the processing gas, it is possible to efficiently discharge the processing gas remaining in the processing gas supply nozzle through the other end, to thereby readily perform the purge of the processing gas nozzle. As a result, it is possible to introduce the plural processing gases into the processing vessel of the substrate processing apparatus by using a single processing gas supply nozzle, and to form a multi-component high dielectric film on the substrate to be processed while reducing the inner volume of the processing vessel. Accordingly, the purge efficiency in the reaction vessel is improved, and the processing can be performed with high throughput.

Further, in accordance with the present invention, the source material to be deposited can be supplied alternately into both sides of the substrate to be processed, so that the film with the uniform thickness can be formed on the substrate to be processed while not being rotated.

Other objects and characteristics of the present invention will be clarified by detailed descriptions performed hereinafter with reference to the drawings.

### BRIEF DESCRIPTION OF THE DRAWINGS

The above and other objects and features of the present invention will become apparent from the following description of preferred embodiments given in conjunction with the accompanying drawings, in which:

FIG. 1 offers a configuration of a conventional substrate processing apparatus;

FIG. 2 shows a magnified part of the substrate processing apparatus of FIG. 1;

FIG. 3 is a configuration of a substrate processing apparatus in accordance with a first embodiment of the present invention;

FIGS. 4A and 4B present additional views for showing configurations of the substrate processing apparatus of FIG. 3;

FIGS. 5A and 5B present views for showing in detail parts of the substrate processing apparatus of FIG. 3;

FIGS. 6A˜6C provide views for showing in detail parts of the substrate processing apparatus of FIG. 3;

FIGS. 7A˜7F offer views for showing substrate processing processes performed by using the substrate processing apparatus of FIG. 3, in accordance with the first embodiment of the present invention;

FIGS. 8A and 8B present views for showing purge effects of a processing gas nozzle;

FIG. 9 describes the number of particles deposited on the substrate in the first embodiment of the present invention;

FIGS. 10A and 10B present views for showing configurations of a processing gas supply nozzle in accordance with a second embodiment of the present invention;

FIG. 11 is a configuration of a substrate processing apparatus in accordance with a third embodiment of the present invention;

FIG. 12 sets forth a view for showing a substrate processing process in accordance with the third embodiment of the present invention; and

FIG. 13 explains a comparative example of the substrate processing process of FIG. 12.

### DETAILED DESCRIPTION OF THE PREFERRED EMBODIMENT

### First Embodiment

FIG. 3 shows a configuration of a substrate processing apparatus 200 in accordance with a first embodiment of the present invention; and FIGS. 4A and 4B describe schematic configurations of the substrate processing apparatus 200. Herein, FIG. 4A is a cross sectional view for simplifying FIG. 3; and FIG. 4B is a plane view of FIG. 4A.

Referring to FIG. 3, the substrate processing apparatus 200 includes an outer vessel 201 made of aluminum alloy, and a cover plate 201A covering the outer vessel 201. In a space formed by the outer vessel 201 and the cover plate 201A, there is installed a reaction vessel 202 forming a processing space.

Further, a lower part of the processing space is configured as a substrate supporting table 203 for supporting a substrate 12 to be processed, wherein the substrate supporting table 203 is downwardly extended from the outer vessel 201 and installed so as to be able to be vertically moved between an upper and a lower position inside a lower vessel 204 provided with a substrate transfer port 204A. The substrate supporting table 203 forms the processing space at the upper position together with the reaction vessel 202.

In the state shown in the drawing, it can be noted that the substrate supporting table 203 is being lowered inside the lower vessel 204, and the substrate 12 to be processed is placed at a position corresponding to the substrate transfer port 204A. In that stage, lifter pins 204B are operated to unload/load the substrate 12.

Further, the substrate supporting table 203 is supported such that it can be rotatably moved by an axis receiving portion 205 containing a magnetic seal; and a bellows 206 is installed around the rotation axis, which is coupled with the substrate supporting table, to facilitate a vertical movement of the substrate supporting table 203.

It can be known that the cover plate 201A is configured to have a thick central portion, so that the space formed by the outer vessel 201 and the cover plate 201A is configured to have a small gap, i.e., volume, at the central portion where the substrate 12 to be processed is disposed, and to have both ends whose gaps are gradually increased, in the state where the substrate supporting table 203 is elevated at the upper position.

In the substrate processing apparatus 200 shown in FIG. 3, high speed rotary valves 25A ad 25B respectively communicating with gas exhaust lines 207a and 207b via gas exhaust ports 255 are installed at both ends of the processing space. Further, at the both ends of the processing space, processing gas nozzles 83A and 83B are installed to respectively face the high speed rotary valves 25A and 25B. Herein, the processing gas nozzles 83A and 83B are formed in bird's beak shapes to rectify a gas flow path to the high speed rotary valve 25A or 25B.

Further, in the configuration of FIG. 3, an outer periphery of the substrate supporting table 203 is covered with a quartz guide ring 203A; and a quartz bottom plate 202A is installed at the bottom portion of the processing space to surround the substrate supporting table 203 from the side, in case where the substrate supporting table 203 is elevated to the upper position.

As described in FIGS. 4A and 4B, the processing gas nozzle 83B is connected to an integrated valve unit 83BI, through which a source gas such as an organic Hf source (Hf—MO) or an organic Al source (TMA), an oxidizing gas such as oxygen, ozone or the like, a nitriding gas such as ammonium or the like, and a purge gas such as Ar or the like, are selectively supplied. Moreover, to the processing gas nozzle 83A, there is connected an integrated valve unit 83AI through which the same source gas, oxidizing gas, nitrifying gas and purge gas are selectively supplied.

FIG. 5A shows configurations of the processing gas nozzle 83B and the integrated valve unit 83BI interacted therewith, which are employed in the substrate processing apparatus 200 shown in FIG. 3; and FIG. 5B shows a magnified view of the vicinity of the processing gas nozzle 83B in FIG. 5A.

Referring to FIGS. 5A and 5B, one end of the processing gas nozzle 83B is exhausted through a vent valve 83BV, and the other end thereof is connected to the integrated valve unit 83BI.

To be more specific, the integrated valve unit 83BI contains a gas line 83BL connected to an opposite end of the processing gas nozzle 83B; and multiple valves 83BV1˜83V7 are connected in common with the gas line 83BL.

Through the valves 83BV1˜83BV5 disposed at the downstream side of the line 83BL, there are supplied source gases from respective source supply lines SB1˜SB5; and vent valves 83Bv1˜83Bv5 corresponding to the respective source supply lines are installed therein. If the vent valve 83BV is closed and one of these valves is selectively opened, the source gas in the corresponding source supply line can be introduced in the form of a laminar flow into the processing space in the reaction vessel 202 via the processing gas nozzle 83B.

Further, the valves 83BV6 and 83BV7, installed at an outer side of the valves 83BV1˜83BV5, are connected to purge gas lines 83BP1 and 83BP2, respectively. Thus, if the vent valve 83BV and the valve 83BV6 are opened, the inside of the processing gas supply nozzle 83B as well as the inside of the gas supply line 83BL, which is connected thereto in a series, can be substantially completely and efficiently purged from one end to the opposite end without leaving the gas by the purge gas such as Ar or the like, which is supplied from the purge gas line 83BP1. Further, if the vent valve 83BV is closed and the valve 83BV7 is opened, the processing space inside the reaction vessel 202 can be purged through the processing gas supply nozzle 83B by the purge gas such as Ar or the like to be supplied through the purge gas line 83BP2. At this time, if the inside of the processing gas supply nozzle 83B is purged in advance, such a problem that the remaining gas residing in the processing gas supply nozzle 83B is discharged to the processing space to thereby result in unnecessary contamination such as chemical adsorption or the like can be prevented.

The same configuration as in FIG. 5A is provided in the processing gas supply nozzle 83A, but explanations of the same configurations and operations will be omitted.

FIGS. 6A to 6C describe configurations of high speed rotary valves 25A and 25B employed in the substrate processing apparatus 200 of FIG. 3.

Referring to FIG. 6A, in the high speed rotary valves 25A and 25B, there are rotatably inserted cylindrical valve bodies 252A and 252B, respectively, wherein openings \textcircled{1} to \textcircled{3} are formed as described in FIGS. 6B and 6C. In FIG. 6A, positions of the openings \textcircled{1} to \textcircled{3} are indicated by arrows in the respective high speed rotary valves 25A and 25B.

Referring to FIG. 6A, to the processing gas supply nozzle 83B, there is connected the integrated valve 83BI containing the valves 83B1 to 83B7. In the same manner, to the processing gas nozzle 83A, there is connected the integrated valve 83AI having the same configuration with the integrated valve 83BI and containing valves 83A1 to 83A7. In the following explanation, the valves 83A1, 83A6 and 83A7 are employed in the integrated valve 83AI, and the valves 83B1, 83B6 and 83B7 are employed in the integrated valve 83BI.

Hereinafter, an example of the ALD processing performed by using the substrate processing apparatus 300 shown in FIG. 3 will be discussed with reference to FIGS. 7A to 7F.

In the processing shown in FIG. 7A, the high speed rotary valves 25A and 25B are set as shown in FIG. 7A, so that the processing space inside the reaction vessel 202 is exhausted through an exhaust line 207a or 207b via a path passing through the openings \textcircled{1} to \textcircled{3}, regardless of the valves, either the valve 25A or 25B. Further, in the state shown in FIG. 7, the opening \textcircled{2}, regardless of the valve, either 25A or 25B, is matched with the processing gas introduction port, either 83A or 83B. As a result, the processing gas introduction port 83A (83B) is also exhausted through the opening \textcircled{3} and the exhaust line 207a.

Next, in the processing shown in FIG. 7B, the state of the high speed rotary valve 25B is the same as that shown in FIG. 7A. The valve body 252 of the high speed rotary valve 25A is rotated to a position where the opening \textcircled{1} communicates with the exhaust line 207a and all the openings \textcircled{2} and \textcircled{3} do not communicate with the processing space or the processing gas introduction port 83B; and the valve 83BV1 in the integrated valve 83BI is opened to introduce the organic metal Hf source material in the line SB1 into the processing space through the processing gas introduction port 83B. The introduced organic metal Hf source material flows through the processing space along the surface of the substrate 12 to be adsorbed thereto.

In the following processing shown in FIG. 7C, the processing space inside the reaction vessel 202 is exhausted through the exhaust line 207b while the positions of the valve bodies 252 in the high speed rotary valves 25A and 25B are kept as they are. Further, in the processing shown in FIG. 7C, the vent valve 83BV (not shown) and the valve 83BV6 in the integrated valve 83BI are opened; Ar purge gas in the line 83BP1 is introduced into the processing gas nozzle 83B; and the introduced Ar purge gas is discharged through the vent valve 83BV to purge the processing gas nozzle 83B. Subsequently, the valve 83BV7 in the integrated valve 83BI is opened; and the Ar purge gas in the line 83BP2 is introduced into the processing space from the processing gas introduction port 83B to purge the processing space.

Next, in the processing shown in FIG. 7D, all the valve bodies 252 in the high speed rotary valves 25A and 25B are turned back to the state shown in FIG. 7A to exhaust the processing space inside the reaction vessel 202.

In the following, in the processing shown in FIG. 7E, the valve body 252 of the high speed rotary valve 25B is rotated to a position where the opening \textcircled{1} communicates with the exhaust line 207b and the openings \textcircled{2} and \textcircled{3} do not communicate with the processing space or the processing gas introduction port 83A while the valve body 252 in the high speed rotary valve 25A is kept as it is. Further, a valve 83AV1 of the integrated valve 83AI is opened, and ozone gas in a line SA1 is introduced into the processing space through the processing gas introduction port 83A. The introduced ozone gas flows through the processing space along the surface of the substrate 12 to oxidize the organic metal Hf source material molecule adsorbed thereto, and thus forming an HfO₂ film having a thickness of one molecular layer.

Subsequently, in the processing shown in FIG. 7F, the processing space inside the reaction vessel 202 is exhausted to the exhaust line 207a while the positions of the valve bodies 252 in the high speed rotary valves 25A and 25B are kept as they are. At this time, in the processing shown in FIG. 7F, the vent valve 83AV and the valve 83AV6 are opened; the Ar purge gas in the line 83AP1 is introduced into the processing gas introduction port 83A; and the introduced Ar purge gas is discharged through the exhaust valve 83AV to purge the processing gas introduction port 83A. Moreover, in the processing shown in FIG. 7F, the valve 83AV7 is opened and the Ar purge gas in the line 83AP2 is introduced into the processing space from the processing gas introduction port 83A to purge the processing space.

Further, by repeatedly performing the processings shown in FIGS. 7A to 7F, it is possible to realize the atomic layer growth of the HfO₂ film on the substrate to be processed 12.

In accordance with the present embodiment, nozzle purge functions are given to the processing gas supply nozzles 83A and 83B, so that different processing gases connected to, e.g., SA2 to SA5 or SB2 to SB5, can be supplied into the processing space from the identical processing gas supply nozzle. Therefore, it is unnecessary to prepare a different processing gas supply nozzle for each processing gas, so that a volume of the processing space can be minimally reduced. Accordingly, the purge of the processing space can be performed in a short time, and the processing efficiency of the atomic layer deposition processing can be significantly improved. At the same time, a multi-component film containing a plurality of metal elements such as ZrSiO₄ or HfAl₂O₅ or the like can be deposited.

FIGS. 8A and 8B offer purge effects of the nozzle in accordance with the present embodiment. However, in the film forming processings whose purging effects are presented in FIGS. 8A and 8B, an Al₂O₃ film is formed on the substrate 12 to be processed by supplying a TMA gas into the processing gas supply nozzle 83A and by supplying the ozone gas into the processing gas supply nozzle 83B.

FIG. 8A shows a result of examination on the uniformity in the film thickness of an obtained Al₂O₃ film, as a function of purge time in the processing gas supply nozzles 83A and 83B. Further, FIG. 8B shows a result of examination on the uniformity in the film thickness of an obtained Al₂O₃ film, as a function of flow rate of the purge gas in the processing gas supply nozzles 83A and 83B. Here, the conditions for the film formation are described in tables 1 to 3, as follows:

TABLE 1

| | |
|---|---|
| TMA supply time | 0.3 seconds |
| TMA supply method | Bubbling by using Ar as a carrier gas |
| | (flow rate of Ar = 40 SCCM) |
| TMA purge | 0~0.3 seconds, 0~0.5 SCCM |
| (inside the nozzle) | |
| TMA purge | Flash purge with Ar of 1000 SCCM |
| (inside the reaction vessel) | |

TABLE 2

| | |
|---|---|
| O₃ supply time | 0.1 seconds |
| O₃ supply method | Injecting O₂ of 1000 SCCM into ozone |
| | generator |
| O₃ purge | 0~0.3 seconds, 0~0.5 SCCM |
| (inside the nozzle) | |
| O₃ purge | Flash purge with Ar of 1000 SCCM |
| (inside the reaction vessel) | |

TABLE 3

| | |
|---|---|
| Film forming temperature | 400° C. |
| Film forming cycle | 250 cycles |

In FIGS. 8A and 8B, ‘▪’ indicates a purge effect in the nozzle 83A to which the TMA gas is supplied, and ‘▴’ indicates a purge effect in the nozzle 83B to which the ozone gas is supplied.

Referring to FIGS. 8A and 8B, it can be known that while the uniformity of the film is about 4% in case when the nozzle purge is not performed, it decreases to about 1 to 2% by increasing the purge time or the flow rate of the purge gas.

FIG. 9 describes the number of particles on the substrate in case where the Al₂O₃ film is formed by using the substrate processing apparatus 200 under the conditions 1 to 3 in table 1. In FIG. 9, [symbol] indicates the initial state before forming a film, and ‘◯’ indicates the state after forming a film.

Referring to FIG. 9, in case where the nozzle exhaust line is not prepared, 1500 or more particles are generated on the substrate after processing. Contrary to this, in case where the vent line 83AV or 83BV described in FIG. 4B is provided, the number of particles generated on the substrate can be suppressed to 50 or less.

### Second Embodiment

FIGS. 10A and 10B describe configurations of the processing gas supply nozzle 83B in accordance with a second embodiment. The same configuration is applied for the processing gas supply nozzle 83A and explanation thereof will be omitted.

Referring to FIG. 10A, the processing gas supply nozzle 83B in accordance with the second embodiment of the present invention is formed of a hollow housing member 83H whose height gets gradually reduced towards the end portion, wherein the hollow housing member 83H is extended from one end to an opposite end and has a slit shaped injection opening 83b at an end portion thereof.

As described in FIG. 10B, in the hollow housing member 83H, there is provided a hollow pipe member 83h to be extended continuously from one end of the hollow housing member 83H to the opposite end thereof. In the hollow pipe member 83h, there are formed plural openings 83p along the longitudinal direction thereof. Further, one end of the hollow pipe member 83h is connected to the vent valve 83BV, and an opposite end thereof is connected to the integrated valve 83BI.

Thus, in case where the processing gas is supplied through the integrate valve 83BI, it is discharged into a space of the hollow housing member 83H from the openings 83p of the hollow pipe member 83h to be uniformized therein, and then discharged in the form of a laminar flow into the processing space in the reaction vessel 202 from the slit shaped injection opening 83b.

Meanwhile, in case where the purge gas is supplied through the integrated valve 83BI, the purge gas from the gas valve 83BV6 is introduced into the opposite end of the hollow pipe member 83h to be discharged from one end through the vent valve 83BV. For the same reason, the inside of the hollow pipe member 83h is purged in sequence from the opposite end to one end, so that it does not remain inside the hollow pipe member 83h.

Further, in the present embodiment, the purge gas line 83BP2 is connected to the hollow housing member 83H, and the valve 83BV7 is installed in the purge line 83BP2 instead of the integrated valve unit 83BI, in order to purge the process space.

### Third Embodiment

FIG. 11 shows a configuration of a substrate processing apparatus 400 using the processing gas supply nozzles 83A and 83B of the prior embodiments, in accordance with a third embodiment of the present invention. In the drawing, parts having substantially the same functions and configurations are designated by the same reference numerals, and their redundant explanations will be omitted unless necessary.

Referring to FIG. 11, in the present embodiment, an Al₂O₃ film is formed on the substrate 12 to be processed while the substrate 12 to be processed is not rotated. Therefore, in the substrate processing apparatus 400, the components, such as the rotation unit 205, the magnetic seal working together therewith and the like, can be omitted, so that the configuration thereof can be substantially simplified.

FIG. 12 describes the formation processing of the Al₂O₃ film.

Referring to FIG. 12, at step 1, the processing gas supply nozzle 83B is closed, and a TMA gas is introduced into the processing space from the processing gas supply nozzle 83A to generate adsorption of TMA molecules on the surface of the substrate 12 to be processed.

In the following, at step 2, the processing gas supply nozzle 83A is purged while the processing gas supply nozzle 83B is closed; and the processing space is purged by the purge gas from the processing gas supply nozzle 83A while the processing gas supply nozzle 83B is closed, at step 3.

In the following, at step 4, the processing gas supply nozzle 83A is closed, and an ozone gas is introduced into the processing space from the processing gas supply nozzle 83B to oxidize the TMA molecules adsorbed on the surface of the substrate 12 to be processed, and thus a molecular layer of Al₂O₃ is formed.

In the following, at step 5, the processing gas supply nozzle 83B is purged while the processing gas supply nozzle 83A is closed; and the processing space is purged by the purge gas from the processing gas supply nozzle 83B while the processing gas supply nozzle 83A is closed, at step 6.

In the following, at step 7, a TMA gas is introduced into the processing space from the processing gas supply nozzle 83B while the processing gas supply nozzle 83A is closed, so that TMA molecules are adsorbed on the surface of the substrate 12 on which the Al₂O₃ molecular layer has been formed in advance.

In the following, at step 8, the processing gas supply nozzle 83B is purged while the processing gas supply nozzle 83A is closed; and the processing space is purged by the purge gas from the processing gas supply nozzle 83B while the processing gas supply nozzle 83A is closed, at step 9.

In the following, at step 10, the processing gas supply nozzle 83B is closed, and an ozone gas is introduced into the processing space from the processing gas supply nozzle 83A to oxidize the TMA molecules adsorbed on the surface of the substrate 12 to be processed, and thus a molecular layer of Al₂O₃ is formed.

In the following, at step 11, the processing gas supply nozzle 83A is purged while the processing gas supply nozzle 83B is closed; and the processing space is purged by the purge gas from the processing gas supply nozzle 83A while the processing gas supply nozzle 83B is closed, at step 12.

In accordance with the present embodiment, since the TMA gas is supplied from both sides of the substrate 12 to be processed, a uniformed Al₂O₃ film can be formed over the entire surface of the substrate 12 to be processed without being rotated. Further, the film thickness can be prevented from being increased in only one side of the substrate 12 to be processed and therefore the film can be prevented from being formed non-uniformly as described in FIG. 13, which is likely to occur in case when plural processing gases are supplied from the same processing gas supply nozzle.

Specifically, the present embodiment is useful for the film forming processing, wherein the film is likely to be formed non-uniformly under a very similar condition for a CVD method in which plural molecular layers are adsorbed on the substrate to be processed by one adsorption process.

Further, in the above-described explanations, examples of forming the Al₂O₃ film on the substrate to be processed have been discussed. However, the present invention is not limited to such a specified source material, and it is applicable to various source materials containing a multi-component material.

Still further, in the aforementioned explanations, examples of forming the high dielectric gate insulating film of a high-speed MOS transistor have been discussed, but the present invention is also useful for the formation of a capacitor having a high dielectric capacitor insulating film, e.g., a memory cell capacitor of DRAM or the like. Still further, the present invention is also aimed at forming a complex shaped structure such as an electrode of the DRAM memory cell capacitor or the like.

While the invention has been shown and described with respect to the preferred embodiments, it will be understood by those skilled in the art that various changes and modifications may be made without departing from the spirit and scope of the invention as defined in the following claims.

In accordance with the present invention, the processing gas is introduced from one end of the processing gas supply nozzle and discharged through an opposite end thereof. Thus, by injecting the purge gas into one end after injecting the processing gas, it is possible to efficiently discharge the processing gas remaining in the processing gas supply nozzle through the opposite end, to thereby readily perform the purge of the processing gas nozzle. As a result, it is possible to introduce the plural processing gases into the reaction vessel of the substrate processing apparatus by using a single processing gas supply nozzle, and to form a multi-component high dielectric film on the substrate to be processed while reducing the inner volume of the reaction vessel. Accordingly, the purge efficiency in the reaction vessel is improved, and the processing on the substrate to be processed can be performed with high throughput.

Further, in accordance with the present invention, the source gas to be deposited can be supplied alternately into both sides of the substrate to be processed, so that the film with the uniform thickness can be formed on the substrate to be processed while not being rotated.

What is claimed is:

1. A substrate processing apparatus comprising:
a reaction vessel having a substrate supporting table for supporting a substrate to be processed; and
a processing gas supply unit for supplying into the reaction vessel a processing gas in the form of a laminar flow along a surface of the substrate,
wherein the processing gas supply unit includes a processing gas nozzle for forming the laminar flow of the processing gas, the processing gas nozzle being provided in the reaction vessel and extended in a direction substantially normal to that of the laminar flow; and
wherein one end of the processing gas nozzle is connected to a processing gas supply line for supplying the processing gas, and an opposite end thereof is connected to an exhaust line.

2. The substrate processing apparatus of claim 1,
wherein the processing gas nozzle includes:
a conduction line extended from a first end corresponding to said one end to a second end corresponding to the opposite end and having plural openings formed along a length direction thereof; and
a nozzle main body having therein a space where the conduction line is accommodated,
wherein the processing gas supply line is connected to the first end of the conduction line, and the exhaust line is connected to the second end of the conduction line.

3. The substrate processing apparatus of claim 1, wherein a slit shaped injection opening for injecting the processing gas is formed in the processing gas nozzle, to be parallel with the surface of the substrate and to be normal to the direction of the laminar flow.

4. The substrate processing apparatus of claim 1, wherein the processing gas nozzle includes:
a hollow member extending from a first end to a second end;
a conduction line accommodated in the hollow member and extended from a third end to a fourth end, the third and the fourth end corresponding to the first and the second end, respectively;
plural openings formed in the conduction line along a length direction thereof;
a slit shaped gas injection opening formed in the hollow member along the extending direction thereof;
a gas introduction port provided at the third end of the conduction line;
a gas exhaust port provided at the fourth end of the conduction line; and
a gas introduction port provided at the hollow member to communicate with an inside thereof.
